(19) United States
(12) Patent Application Publication
(10) Pub. No.: US 2007/0096280 A1
(43) Pub. Date: May 3, 2007

(54) Image sensor module structure and a method for manufacturing the same

(76) Inventors: Hsiu Wen Tu, Hsinchu Hsien (TW); Chen Pin Peng, Hsinchu Hsien (TW); Mon Nan Ho, Hsinchu Hsien (TW); Chung Hsien Hsin, Hsinchu Hsien (TW)

Correspondence Address: PRO-TECHTOR INTERNATIONAL SERVICES, 20775 NORADA CT., SARATOGA, CA, 95070, US

(21) Appl. No.: 11/265,068

(22) Filed: Nov. 1, 2005

(51) Int. Cl. H01L 23/02

(52) U.S. Cl. 257/680

(57) ABSTRACT

An image sensor module structure and method for manufacturing the same includes a substrate having an upper surface and a lower surface, a chip is mounted on the upper surface of the substrate, a plurality of wires are electrically connected the bonding pads of the chip to the first electrodes of the substrate, an adhered layer is coated on the upper surface of the substrate, a lens holder has a lateral wall and internal thread, the lateral wall is adhered on the upper surface of the substrate by the adhered layer to encapsulate the chip, so that the adhered layer is pressed to cover the wires, and a lens barrel is formed with external thread screwed on the internal thread of the lens holder.

### BACKGROUND OF THE INVENTION

1. Field of the Invention

The invention relates an image sensor module structure and a method for manufacturing the same, and particular to a structure for packaging image sensor module, the manufacturing cost may be decreased, and the size of the package may be decreased.

2. Description of the Related Art

Referring to FIG. 1, it is an image sensor module structure includes a substrate 10, a chip 20, a plurality of wires 24, an adhered layer 26, a lens holder 28 and a lens barrel 32.

The substrate 10 has an upper surface 12 on which plurality of first electrodes 16 are formed, and a lower surface 14 on which plurality of second electrodes 18 are formed, the first electrodes 16 are corresponding to electrically connect to the second electrodes 18. The chip 20 is arranged on the upper surface 12 of the substrate 101, and is formed with bonding pads 22. Each wire 24 is electrically connected the bonding pad 22 to the first electrodes 16 of the substrate 10. The adhered layer 26 is coated on the upper 12 of the substrate 10. The lens holder 28 is formed with internal thread 30, and is adhered on the upper surface 12 of the substrate 10 by the adhered layer 26. The lens barrel 32 is formed with external thread 34 screwed on the internal thread 30 of the lens holder 28.

Therefore, the adhered layer 26 may be flowed to out of the lens holder 28 to product a bigger size of module, so that the reliability of the product is decreased.

### SUMMARY OF THE INVENTION

An objective of the invention is to provide an image sensor module structure and a method for manufacturing the same, and capable of decreasing the manufacturing cast of the image sensor.

An objective of the invention is to provide an image sensor module structure a method for manufacturing the same, and capable of decreasing the size of the structure.

To achieve the above-mentioned object, the invention includes An image sensor module structure and method for manufacturing the same includes a substrate having an upper surface and a lower surface, a chip is mounted on the upper surface of the substrate, a plurality of wires are electrically connected the bonding pads of the chip to the first electrodes of the substrate, a adhered layer is coated on the upper surface of the substrate, a lens holder has a lateral wall and internal thread, the lateral wall is adhered on the upper surface of the substrate by the adhered layer to encapsulate the chip, so that the adhered layer is pressed to cover the wires, cutting the lateral wall of the lens holder and the substrate adhered on the lateral wall of the lens holder; and a lens barrel is formed with external thread screwed on the internal thread of the lens holder.

### BRIEF DESCRIPTION OF THE DRAWINGS

FIG. 1 is a schematic illustration showing a conventional image sensor module structure.

FIG. 2 is a first schematic illustration showing an image sensor module structure.

FIG. 3 is a second schematic illustration showing an image sensor module structure.

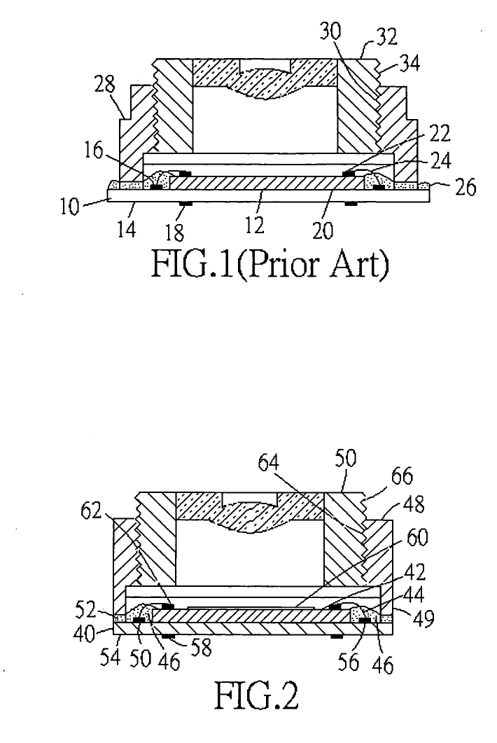

### DETAILED DESCRIPTION OF THE INVENTION

Please refer to FIG. 2, an image sensor module structure of the present invention includes substrate 40, a chip 42, wires 44, an adhered layer 46, lens holder 48, and a lens barrel 50.

The substrate 40 has an upper surface 52, which is formed with first electrodes 56, and a lower surface 54, which is formed with second electrodes 58 corresponding to electrically connect to the first electrodes 56 The chip 42 is mounted on the upper surface 52 of the substrate 40, the chip 42 has a sensor region 60 and a plurality of bonding pads 62 located at the side of the sensor region 60 of the chip 42.

The plurality of wires 44 are electrically connected the bonding pads 62 of the chip 40 to the first electrodes 56 of the substrate 40.

The adhered layer 46 is coated on the upper surface 52 of the substrate 40.

The lens holder 48 has a lateral wall 49 and internal thread 64, the lateral wall 49 is adhered on the upper surface 52 of the substrate 40 by the adhered layer 46 to encapsulate the chip 40, so that the adhered layer 46 is pressed to cover the wires 44 and chip 42 to fix the chip 42.

The lens barrel 50 is formed with external thread 66 screwed on the internal thread 64 of the lens holder 48.

Cutting the lateral wall 49 of the lens holder 48 and the substrate 40 adhered on the lateral wall 49 of the lens holder 48.

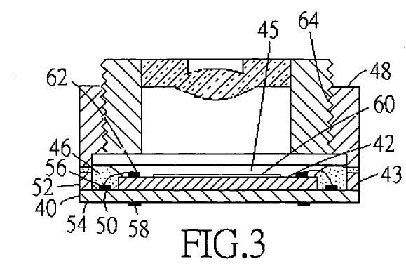

Please refer to FIG. 3, wherein the present invention includes a frame layer 43 mounted on the upper surface 52 of the substrate 40, a cavity 45 is formed between the substrate 40 and the frame layer 43. The adhered layer 46 is coated on the frame layer 43, the lateral wall 49 of the lens holder 48 is adhered on the frame layer 43 to press the adhered layer 43 to cover the wires 44 and chip 42.

Cutting the lateral wall 49 of the lens holder 48, frame layer 43, and the substrate 40 adhered on the lateral wall 49 of the lens holder 48 to product a signal module.

While the invention has been described by the way of an example and in terms of a preferred embodiment, it is to be understood that the invention is not limited to the disclosed embodiment. On the contrary, it is intended to cover various modifications. Therefore, the scope of the appended claims should be accorded the broadest interpretation so as to encompass all such modifications.

What is claimed is:

1. An image sensor module structure, the structure comprising;
a substrate having an upper surface, which is formed with first electrodes, and a lower surface, which is formed with second electrodes corresponding to electrically connect to the first electrodes;
a chip mounted on the upper surface of the substrate, the chip having a sensor region and a plurality of bonding pads located at the side of the sensor region of the chip;
a plurality of wires electrically connected the bonding pads of the chip to the first electrodes of the substrate;
an adhered layer coated on the upper surface of the substrate;
a lens holder having a lateral wall and internal thread, the lateral side of the lens holder adhered on the upper surface of the substrate by the adhered layer to encapsulate the chip, so that the adhered layer is pressed to cover the wires; and
a lens barrel formed with external thread screwed on the internal thread of the lens holder.

2. The image sensor module structure according to claim 1, wherein the upper surface of the substrate is formed with a frame layer, the adhered layer is coated on the frame layer, so that the lateral wall of the lens holder is adhered on the frame layer by the adhered layer.

3. The image sensor module structure according to claim 1, wherein the adhered layer is covered on the chip to fix the chip.

4. A method for manufacturing an image sensor module structure, comprising the steps of:
Providing a substrate having an upper surface, which is formed with first electrodes, and a lower surface, which is formed with second electrodes corresponding to electrically connect to the first electrodes;
Providing a chip mounted on the upper surface of the substrate, the chip having a sensor region and a plurality of bonding pads located at the side of the sensor region of the chip;
Providing a plurality of wires electrically connected the bonding pads of the chip to the first electrodes of the substrate;
Providing a adhered layer coated on the upper surface of the substrate;
Providing a lens holder having a lateral wall and internal thread, the lateral of the lens holder wall adhered on the upper surface of the substrate by the adhered layer to encapsulate the chip, so that the adhered layer is pressed to cover the wires;
Cutting the lateral wall of the lens holder and the substrate adhered on the lateral wall of the lens holder; and
Providing a lens barrel formed with external thread screwed on the internal thread of the lens holder.

5. The method according to claim 4, wherein the upper surface of the substrate is formed with a frame layer, the adhered layer is coated on the frame layer, so that the lateral wall of the lens holder is adhered on the frame layer by the adhered layer, to cut the lateral wall of the lens holder and the substrate adhered on the lateral wall of the lens holder.
